(19) United States
(12) Patent Application Publication
(10) Pub. No.: US 2026/0082594 A1
(43) Pub. Date: Mar. 19, 2026

(54) CFET, DCAP CELL, AND METHOD OF FORMING THE SAME

(71) Applicant: TAIWAN SEMICONDUCTOR MANUFACTURING COMPANY, LTD., Hsinchu (TW)

(72) Inventors: Wei-Cheng KANG, Hsinchu (TW); Meng-Hung SHEN, Hsinchu (TW); Hung-Li CHIANG, Hsinchu (TW); Chun-Yen LIN, Hsinchu (TW); Jiann-Tyng TZENG, Hsinchu (TW)

(21) Appl. No.: 19/009,272

(22) Filed: Jan. 3, 2025

Related U.S. Application Data
(60) Provisional application No. 63/695,136, filed on Sep. 16, 2024.

(51) Int. Cl. H10D 1/66; H10D 1/00

(52) U.S. Cl. CPC H10D 1/66; H10D 1/047

(57) ABSTRACT

A complementary field effect transistor (CFET) includes first source/drain regions of a first conductivity type; an insulating layer on the first source/drain regions; second source/drain regions of a second conductivity type on the insulating layer, the second conductivity type being different from the first conductivity type; vertical connecting structures extending through the insulating layer and electrically connecting the first source/drain regions with the second source/drain regions, the first and second source/drain regions being configured to receive a same first reference voltage; a first channel region corresponding to the first source/drain regions; a second channel region corresponding to the second source/drain regions; and a gate structure that is common to and at least partially surrounds the first channel region and the second channel region, the gate structure being configured to receive a second reference voltage different from the first reference voltage.

### PRIORITY CLAIM

This application claims the benefit of U.S. Provisional Application No. 63/695,136, filed Sep. 16, 2024, which is herein incorporated by reference in its entirety.

### BACKGROUND

Advances in integrated circuit (IC) technology have resulted in smaller devices that consume less power yet provide more functionality at higher speeds. Demands for greater functionality in modern devices results in more complex devices and poses challenges for continued miniaturization.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a decoupling capacitor (DCAP) cell according to some embodiments.

FIG. 2A is a cross-sectional diagram of a structure of a complementary field effect transistor (CFET) according to some embodiments.

FIG. 2B is a cross-section along a line I-I′ in FIG. 2A.

FIG. 2C is a cross-section along a line II-II′ in FIG. 2A.

FIG. 2D is a schematic diagram of a CFET showing capacitive features according to some embodiments.

FIG. 2E is a cross-sectional diagram of a structure of a CFET according to some embodiments.

FIG. 2F is a cross-section along a line III-III′ in FIG. 2E.

FIG. 3 is a schematic diagram of a DCAP cell according to some embodiments.

FIG. 4A is a cross-sectional diagram of a structure of a CFET-like structure according to some embodiments.

FIG. 4B is a cross-section along a line I-I′ in FIG. 4A.

FIG. 4C is a cross-section along a line II-II′ in FIG. 4A.

FIG. 4D is a schematic diagram of a CFET showing capacitive features according to some embodiments.

FIG. 5 is a flowchart of a method of manufacturing a semiconductor device according to some embodiments.

FIG. 6 is a flowchart of a method of manufacturing a semiconductor device according to some embodiments.

FIG. 7 is a block diagram of an electronic design automation (EDA) system according to some embodiments.

FIG. 8 is a block diagram of an integrated circuit (IC) manufacturing system, and an IC manufacturing flow associated therewith, according to some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments relate to a decoupling capacitor (DCAP) cell as well as CFET structures configured to provide capacitance for the DCAP cell and/or other circuits or circuit elements for which capacitive devices are useful. Embodiments can provide one or more of high capacitance, small footprint (e.g., cell area or die area), and/or simple wiring (e.g., in-cell routing). Embodiments can employ n-type metal oxide semiconductor (NMOS) transistors and/or p-type metal oxide semiconductor (PMOS) transistors to provide capacitance while helping to minimize or avoid excessive leakage (e.g., gate oxide leakage or well leakage).

In some embodiments, a CFET is configured as a capacitor, e.g., as a decoupling capacitor. In some embodiments, NMOS and PMOS transistors of the CFET are both used to provide capacitance. In some embodiments, some portions of one of the transistors, e.g., an NMOS transistor (or a PMOS transistor), are omitted while other portions of the transistor are maintained and provide capacitance for the capacitor.

In some embodiments, a CFET includes an NMOS transistor and PMOS transistor in a vertical arrangement having one of the transistors stacked on the other. In some embodiments, a PMOS transistor is formed on a substrate and an NMOS transistor is formed on the PMOS transistor. In some embodiments, an NMOS transistor is formed on a substrate and a PMOS transistor is formed on the NMOS transistor. Embodiments are not limited to a particular stacking order. In some embodiments, forming the CFET includes sequentially forming one transistor after the other, and in other embodiments forming the CFET includes forming one or more features of both transistors concurrently. In some embodiments, the NMOS transistor is well-free.

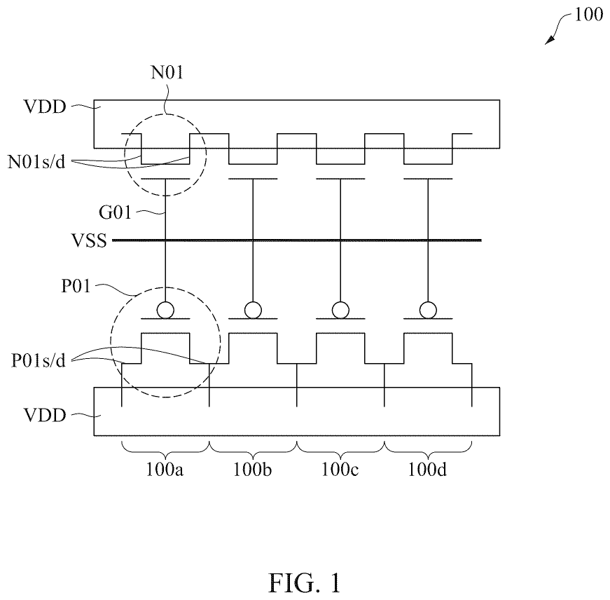

FIG. 1 is a schematic diagram of a decoupling capacitor (DCAP) cell 100 according to some embodiments.

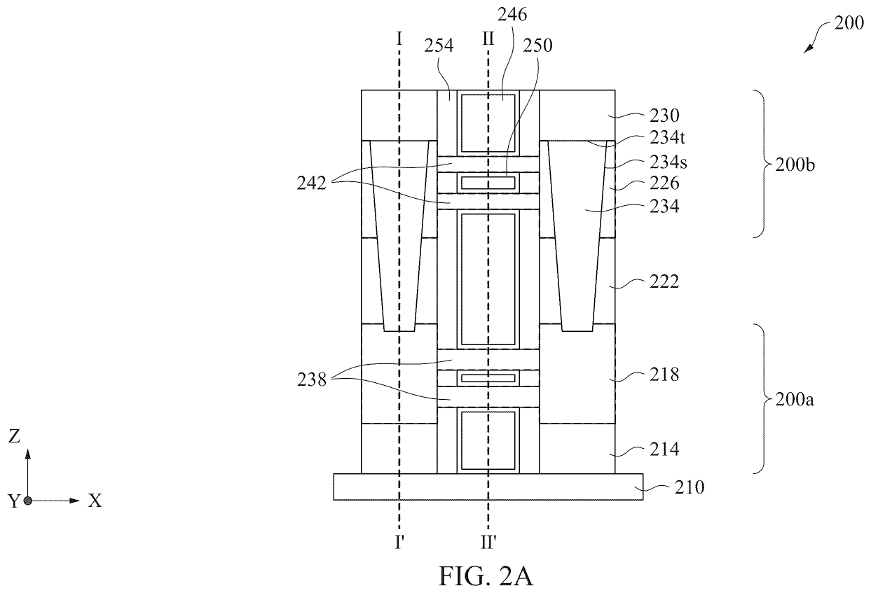

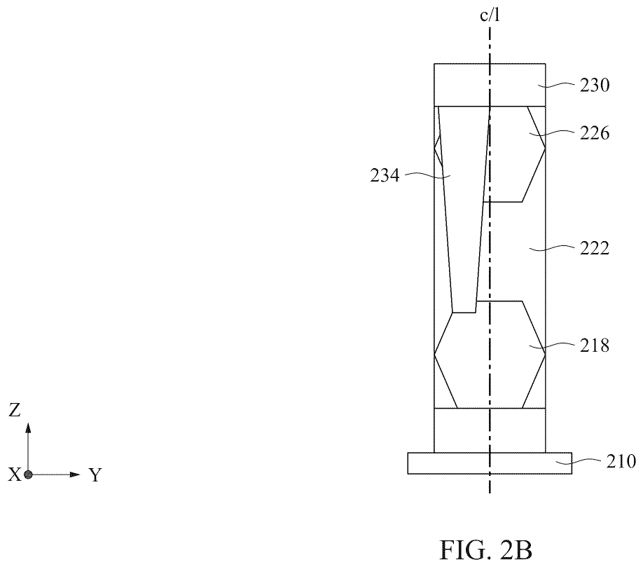

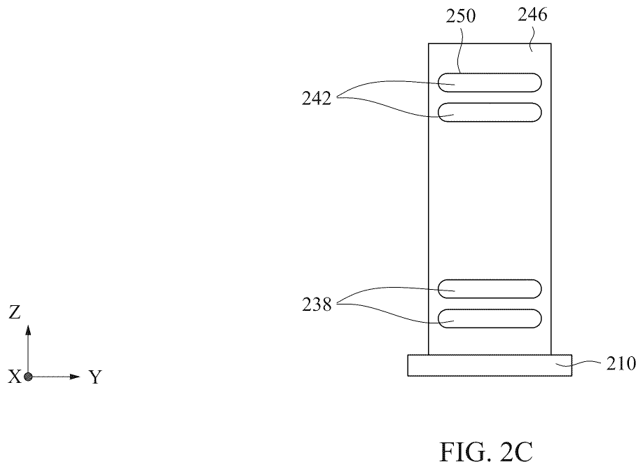

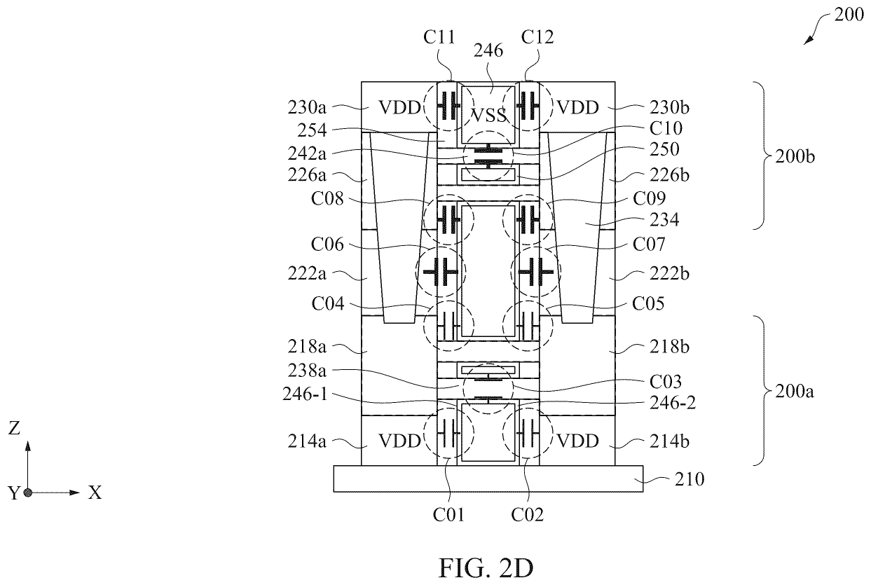

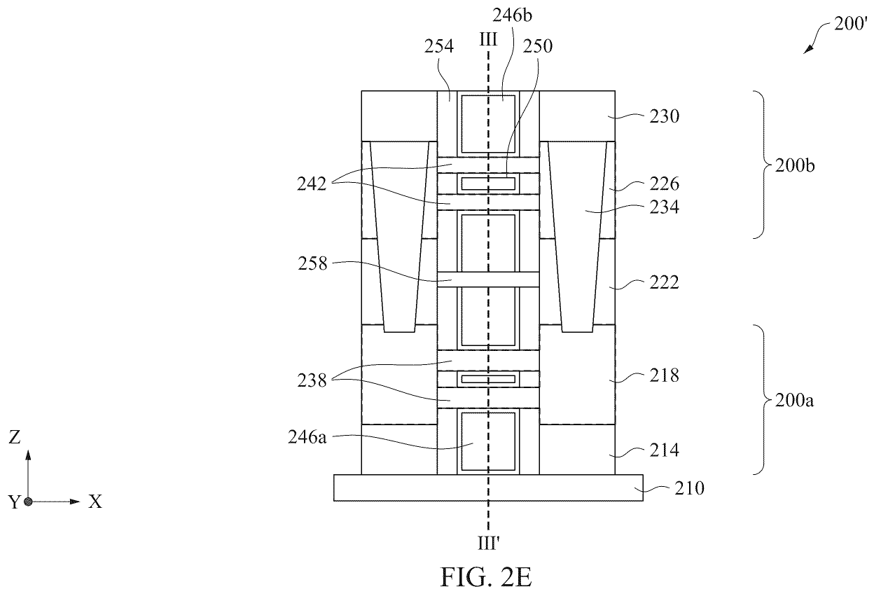

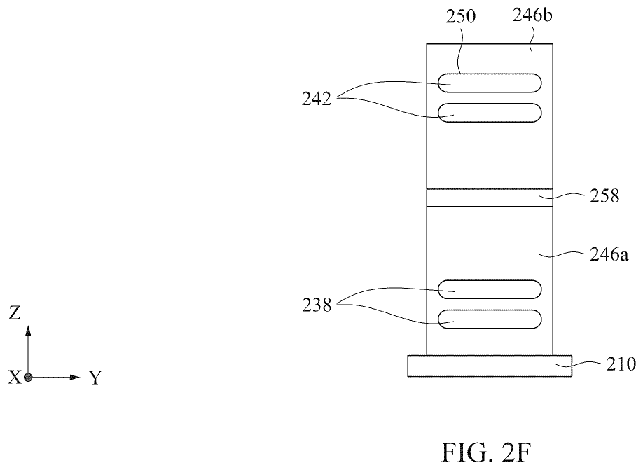

In some embodiments, the DCAP cell 100 corresponds to a decoupling circuit that is included in an integrated circuit device that includes a plurality of cells. In FIG. 1, the DCAP cell 100 according to some embodiments includes four CFET devices 100a-100d by way of example. In other embodiments, the number of CFET devices is different, e.g., one, two, three, or more than four. First CFET device 100a includes a first PMOS transistor P01 and a first NMOS transistor N01, which have a common gate G01. The second through fourth CFET devices 100b-100d also each include an NMOS transistor and a PMOS transistor with respective common gates. Source/drain (s/d) regions P01s/d of the first PMOS transistor P01 and s/d regions N01s/d of the first NMOS transistor N01 are all supplied with a first reference voltage, e.g., a constant voltage, e.g., VDD, while the common gate G01 is supplied with a second reference voltage different from the first reference voltage, e.g., VSS. This configuration has the effect of reverse-biasing the NMOS transistor N01. The second through fourth CFET devices 100b-100d are coupled in parallel to the first CFET device 100a and thus the NMOS transistors of the second through fourth CFET devices 100b-100d are also reverse-biased. As described in further detail below in connection with FIGS. 2A-2D, the DCAP cell 100 thus configured to reverse-bias the NMOS transistors provides additional capacitance relative to a DCAP cell using CFETs that employ only one transistor of each CFET, e.g., the PMOS transistor, to provide capacitance, while keeping gate leakage across a gate oxide layer low in the NMOS transistors. Further, the advantage of increased capacitance provided by the DCAP cell 100 is achieved without an increase in cell size relative to a DCAP cell using CFETs that employ only one transistor of each CFET, e.g., the PMOS transistor, to provide capacitance. In some embodiments, the DCAP cell 100 is implemented using a split-gate configuration that employs an inversion charge on a channel to increase capacitance.

FIG. 2A is a cross-sectional diagram of a structure of a CFET 200 according to some embodiments. FIG. 2B is a cross-section along a line I-I′ in FIG. 2A. FIG. 2C is a cross-section along a line II-II′ in FIG. 2A.

In FIG. 2A, the CFET 200 according to some embodiments includes a first transistor 200a, e.g., a PMOS transistor on a substrate 210 and a second transistor 200b, e.g., an NMOS transistor on the first transistor 200a, in a vertical arrangement such that, relative to a Z-axis direction, the first transistor 200a is between the substrate 210 and the second transistor 200b (it will be appreciated that the positioning of the PMOS and NMOS transistors is flexible, and that descriptions of the PMOS transistor being between the substrate 210 and the NMOS transistor likewise apply to the CFET 200 including the NMOS transistor being between the substrate 210 and the PMOS transistor). In some embodiments, the CFET 200 is configured as a CFET decoupling capacitor device and corresponds to any of CFET devices 100a-100d of FIG. 1.

In FIG. 2A, the CFET 200 includes a pair of first conductive structures 214 spaced apart laterally in an X-axis direction on the substrate 210, a pair of first source/drain structures 218, e.g., p-type epitaxial (PEPI) structures or n-type EPI (NEPI) structures, on corresponding ones of the first conductive structures 214, a pair of insulating structures 222 on corresponding ones of the first source/drain structures 218, a pair of second source/drain structures 226, e.g., NEPI or PEPI structures, on corresponding ones of the insulating structures 222, and a pair of second conductive structures 230 on corresponding ones of the second source/drain structures 226. Herein, it will be understood that references to insulators, insulating structures, or the like encompass the use of dielectric materials unless stated otherwise or otherwise apparent. The CFET 200 also includes a pair of vertical electrical connections 234 extending in the Z-axis direction between and connecting corresponding ones of the first source/drain structures 218 and the second conductive structures 230. The CFET 200 also includes first channel regions 238 extending in the X-axis direction between the first source/drain structures 218, and second channel regions 242 extending in the X-axis direction between the second source/drain structures 226. A gate structure 246 extends in the Z-axis direction and at least partially surrounds the first and second channel regions 238, 242. In some embodiments, the gate structure 246 fully surrounds each of the first and second channel regions 238, 242. The gate structure 246 is between ones of the pair of first conductive structures 214 and between ones of the pair of second conductive structures 230 relative to the X-axis direction. The gate structure 246 is at least partially covered by a gate isolation layer 250, e.g., a gate oxide layer. The gate isolation layer 250 is between the gate structure 246 and the first and second channel regions 238, 242. An insulating structure 254 surrounds the gate structure 246. In some embodiments, the insulating structure 254 includes an oxide of silicon, silicon nitride, SiOCN, or the like. In some embodiments, the insulating structure 254 is formed by, e.g., a deposition process or an oxidation process. In some embodiments, the insulating structure 254 is integral with the insulating structures 222. In other embodiments, the insulating structure 254 and the insulating structures 222 are formed separately and/or formed of different insulating materials.

In further detail, in FIG. 2A, the first conductive structures 214 are conductive structures that are formed in a BMD layer (which may be referred to as a bottom metal-under-diffusion layer or metal-on-diffusion layer) on the substrate 210 or on wiring (not shown) that is on the substrate 210, between the substrate 210 and the CFET 200. The first conductive structures 214 may be referred to as BMD structures.

In some embodiments, the substrate 210 is a semiconductor substrate. In some embodiments, the substrate 210 is a silicon substrate, a silicon-germanium substrate, a silicon carbide substrate, a gallium arsenide substrate, or the like. In some embodiments, the substrate 210 includes silicon and another elemental semiconductor such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate 210 is a semiconductor-on-insulator (SOI) substrate, e.g., a silicon-on-insulator substrate. In some embodiments, the substrate 210 includes a doped epi layer, a gradient semiconductor layer, and/or a semiconductor layer overlying another semiconductor layer of a different type, such as a silicon layer on a silicon germanium layer. In some embodiments, the substrate 210 includes doped regions such as a p-well, an n-well, or both. In some embodiments, the substrate 210 is a dielectric substrate, a sapphire substrate, or the like.

The first conductive structures 214 form source/drain contacts for the lower transistor in the CFET 200, e.g., the first transistor 200a. The first conductive structures 214 include one or more conductive materials such as a metal, a metal compound, a doped semiconductor, or the like. In some embodiments, the first conductive structures 214 include one or more metals such as Al, Co, Cu, Ru, W, or the like. In some embodiments, the first conductive structures 214 include one or more metal compounds such as AlCu, NiSiₓ, TaN, TiN, TiSiₓ, WTiN, or the like. In some embodiments, the first conductive structures 214 include one or more a doped semiconductors such as doped Si, doped SiGe, or the like.

In some embodiments, the first conductive structures 214 are on conductive segments (e.g., metal segments) (not shown) in a first conductive layer (e.g., a metal layer), which may be referred to as BM0, that is under the CFET 200. In some embodiments, the first conductive layer BM0 is between the CFET 200 and the substrate 210. In other embodiments, the first conductive layer BM0 is a backside conductive layer that is on a backside of the substrate 210 such that the substrate 210 is between the CFET 200 and the first conductive layer BM0. Conductive layers (e.g., metal layers) that are under the first conductive layer BM0 are referred to as BM1, BM2, and the like, with BM1 being between BM2 and BM0. Via structures (not shown) extend between the conductive layers to couple the conductive segments, where BV0 is a bottom via layer or back side via layer arranged between and electrically coupling the BM0 layer and the BM1 layer, and via layers BV1, BV2, and the like are used to couple lower conductive layers.

The first source/drain structures 218 are on and in electrical contact with corresponding ones of the first conductive structures 214. A first first source/drain structure 218 is at a first side 246-1 of the gate structure 246 and a second first source/drain structure 218 is at a second side 246-2 of the gate structure 246. In some embodiments, PEPI structures include one or more of GeSnB, SiGeB, or the like. In some embodiments, NEPI structures include one or more of AlGaAs, GaAs, GaAsP, Ge, Si, SiGe, SiP, or the like. In some embodiments, the first source/drain structures 218 are formed by epitaxial growth from the first channel regions 238. In other embodiments, the first source/drain structures 218 are formed by epitaxial growth from another portion of the first transistor 200a or from an intermediate or sacrificial structure. Epitaxy processes usable to form the first source/drain structures 218 include, e.g., chemical vapor deposition (CVD), ultra-high vacuum CVD (UHV-CVD), low-pressure CVD (LPCVD), plasma-enhanced CVD (PECVD), selective epitaxial growth (SEG), vapor-phase epitaxy (VPE), molecular beam epitaxy (MBE), and the like. In some embodiments, PEPI structures are in-situ doped during the epitaxial process by introducing p-type dopants such as boron or BF₂. In some embodiments, NEPI structures are in-situ doped during the epitaxial process by introducing n-type dopants such as phosphorus or arsenic. In other embodiments, an implantation process is performed to dope the first source/drain structures 218.

The first channel regions 238 extend between ones of the first source/drain structures 218. In some embodiments, the first channel regions 238 are active regions that include nanostructures such as nanosheets or nanowires. In FIG. 2A, the first transistor 200a includes two first channel regions 238. In other embodiments, only one first channel region 238 is provided, and in still other embodiments, more than two first channel regions 238 are provided. In some embodiments, each first channel region 238 includes a plurality of nanostructures. In some embodiments, the nanostructures are silicon nanostructures, e.g., silicon nanosheets or the like. In some embodiments, forming the silicon nanostructures includes forming alternating layers of SiGe and Si in a vertical stack, e.g., by sequentially forming SiGe and Si layers using an epitaxial process such one of the epitaxial processes described above, and then selectively removing the SiGe layers, e.g., using a selective etch, such that the Si layers remain as the first channel regions 238.

In some embodiments, the insulating structures 222 on the first source/drain structures 218 are included in a middle dielectric isolation (MDI) layer. The insulating structures 222 and/or the MDI layer isolate the active structures of the second transistor 200b from the active structures of the first transistor 200a. In some embodiments, the insulating structures 222 include an oxide of silicon, silicon nitride, SiOCN, or the like. In some embodiments, the insulating structures 222 are formed by, e.g., a deposition process or an oxidation process. In some embodiments, the second transistor 200b is formed on a different substrate from a substrate on which the first transistor 200a is formed and then the substrates are joined together, and the MDI layer is an exposed layer of one of the substrates such that the MDI layer is located at an interface of the substrates after the substrates are joined.

The second source/drain structures 226 are over the insulating structures 222 and are in electrical contact with corresponding ones of the overlying second conductive structures 230. A first second source/drain structure 226 is at the first side of the gate structure 246 and a second second source/drain structure 226 is at the second side of the gate structure 246. In some embodiments, PEPI structures include one or more of GeSnB, SiGeB, or the like. In some embodiments, NEPI structures include one or more of AlGaAs, GaAs, GaAsP, Ge, Si, SiGe, SiP, or the like. In some embodiments, the second source/drain structures 226 are formed by epitaxial growth from the second channel regions 242. In other embodiments, the second source/drain structures 226 are formed by epitaxial growth from another portion of the second transistor 200b or from an intermediate or sacrificial structure. Epitaxy processes usable to form the second source/drain structures 226 include those described above for forming the first source/drain structures 218. In some embodiments, PEPI structures are in-situ doped during the epitaxial process by introducing p-type dopants such as boron or BF₂. In some embodiments, NEPI structures are in-situ doped during the epitaxial process by introducing n-type dopants such as phosphorus or arsenic. In other embodiments, an implantation process is performed to dope the second source/drain structures 226.

The second channel regions 242 extend between ones of the second source/drain structures 226. In some embodiments, the second channel regions 242 are active regions that include nanostructures such as nanosheets or nanowires. In FIG. 2A, the second transistor 200b includes two second channel regions 242. In other embodiments, only one second channel region 242 is provided, and in still other embodiments, more than two second channel regions 242 are provided. In FIG. 2A, the number of first channel regions 238 is equal to the number of second channel regions 242. In other embodiments, the number of first channel regions 238 is different from the number of second channel regions 242, and/or the first channel regions 238 have different dimensions relative to the second channel regions 242. In some embodiments, each second channel region 242 includes a plurality of nanostructures. In some embodiments, the nanostructures are silicon nanostructures, e.g., silicon nanosheets or the like. In some embodiments, forming the silicon nanostructures includes forming alternating layers of SiGe and Si in a vertical stack, e.g., by sequentially forming SiGe and Si layers using an epitaxial process such one of the epitaxial processes described above, and then selectively removing the SiGe layers, e.g., using a selective etch, such that the Si layers remain as the second channel regions 242.

The second conductive structures 230 form source/drain contacts for the upper transistor in the CFET 200, i.e., the second transistor 200b. The second conductive structures 230 are conductive structures that are formed in an MD layer (which may be referred to as a metal-on-diffusion layer). The second conductive structures 230 may be referred to as MD structures. The second conductive structures 230 are in electrical contact with the second source/drain structures 226. The second conductive structures 230 include one or more conductive materials such as a metal, a metal compound, a doped semiconductor, or the like. In some embodiments, the second conductive structures 230 include one more metals such as Al, Co, Cu, Ru, W, or the like. In some embodiments, the second conductive structures 230 include one or more metal compounds such as AlCu, NiSix, TaN, TiN, TiSix, WTiN, or the like. In some embodiments, the second conductive structures 230 include one or more a doped semiconductors such as doped Si, doped SiGe, or the like. In some embodiments, the second conductive structures 230 are formed of the same material(s) as the first conductive structures 214. In other embodiments, the second conductive structures 230 are formed of different material(s) from the first conductive structures 214.

The vertical electrical connections 234 are formed of a conductive material that extends to connect corresponding ones of the first source/drain structures 218 and the second conductive structures 230. A first vertical electrical connection 234 is on the first side of the gate structure 246 and a second vertical electrical connection 234 is on the second side of the gate structure 246. The vertical electrical connections 234 are in electrical contact with the second conductive structures 230. In some embodiments, the vertical electrical connections 234 are formed before the second conductive structures 230, and top surfaces 234t of the vertical electrical connections 234 are exposed to make electrical contact with bottom surfaces of the second conductive structures 230. In other embodiments, the vertical electrical connections 234 are formed to penetrate the second conductive structures 230 and are in electrical contact with the second conductive structures where the vertical electrical connections 234 penetrate the second conductive structures 230. The vertical electrical connections 234 penetrate the second source/drain structures 226. In some embodiments, sidewalls 234s of the vertical electrical connections 234 are in electrical contact with the second source/drain structures 226 where the vertical electrical connections 234 pass through the second source/drain structures 226. In other embodiments, the sidewalls 234s are covered with an insulating layer or material, and the vertical electrical connections 234 are electrically connected to the second source/drain structures 226 by way of the second conductive structures 230. In FIG. 2A, the vertical electrical connections 234 extend partially into the first source/drain structures 218. In some embodiments, the vertical electrical connections 234 extend through less than a half-height of the first source/drain structures 218. In other embodiments, the vertical electrical connections 234 extend completely through the first source/drain structures 218 to connect to the first conductive structures 214.

In FIG. 2A, the CFET 200 is configured as a capacitor, and the first source/drain structures 218 and the second source/drain structures 226 are all supplied with a same first reference voltage. Other CFETs (e.g., in logic gates adjacent to the CFET 200) that are not configured as capacitors do not include the vertical electrical connections 234 connecting to the first source/drain structures 218. For example, a cell layout according to some embodiments includes a first cell and a second cell adjacent to the first cell, the first cell being a DCAP cell including one or more CFETs configured as capacitors and including vertical electrical connections 234 that connect all sources and drains of the PMOS and NMOS transistors to a same reference voltage (e.g., VDD), and the second cell being a logic cell including CFETs that are free of the vertical electrical connections 234.

FIG. 2B is a cross-section along a line I-I′ in FIG. 2A, corresponding to a location of the vertical electrical connection 234 at the first side of the gate structure 246. In FIG. 2B, the vertical electrical connection 234 penetrates the second source/drain structure 226 and extends partially into the first source/drain structure 218. The vertical electrical connection 234 electrically connects the second conductive structure 230 (e.g., an MD contact) to the first source/drain structure 218 such that the second source/drain structure 226 and the first source/drain structure 218 are configured to be at a same voltage potential, e.g., VDD.

In FIG. 2B, the center of the vertical electrical connection 234 is offset relative to a centerline c/l of the first and second source/drain structures 218, 226. In other embodiments, the vertical electrical connection 234 is substantially centered relative to centerline c/l of the first and second source/drain structures 218, 226. In FIG. 2B, insulating structure 222 is shown as extending from a top of the second source/drain structure 226 to a bottom of the first source/drain structure 218, as well as extending laterally between the first source/drain structure 218 and the second source/drain structure 226. In some embodiments, the insulating structure 222 is a monolithic structure. In other embodiments, the insulating structure 222 is formed of two or more insulating structures, e.g., the MDI layer between the first source/drain structure 218 and the second source/drain structure 226, and additional insulating structures above and below the MDI layer.

FIG. 2C is a cross-section along a line II-II′ in FIG. 2A, corresponding to a location of the gate structure 246. In some embodiments, the gate structure 246 is a metal gate that includes one or more metal layers. In other embodiments, the gate structure includes a conductive material such as a semiconductor or doped semiconductor, e.g., polysilicon or the like. In some embodiments, the gate structure 246 is formed after removal of intermediate or sacrificial structures, e.g., SiGe layers, between the first channel regions 238 and between the second channel regions 242. In some embodiments, the gate structure 246 has a same construction or configuration at the first transistor 200a as at the second transistor 200b. In other embodiments, a structure or material of the gate structure 246 is varied along a height of the gate structure, e.g., such that materials and/or layers of the gate structure 246 are different in the first transistor 200a relative to the second transistor 200b. The gate isolation layer 250 is on outer surfaces of the gate structure 246 at the first and second channel regions 238, 242, so as to isolate the gate structure 246 from each of the first channel regions 238 and the second channel regions 242. FIG. 2C shows the gate isolation layer 250 extending along surfaces of the gate structure 246 at regions apart from the first and second channel regions 238, 242, but it will be understood that other insulating structures can be used instead of the gate isolation layer 250 at the regions apart from the first and second channel regions 238, 242.

Although not shown in FIG. 2A, in some embodiments conductive segments (e.g., metal segments) in a first conductive layer (e.g., a metal layer), which may be referred to as M0, are on the second conductive structures 230. Conductive layers (e.g., metal layers) that are over the first conductive layer M0 are referred to as M1, M2, and the like, with M1 being between M2 and M0. Via structures (not shown) extend between the conductive layers to couple the conductive segments, where V0 is a via layer arranged between and electrically coupling the M0 layer and the M1 layer, and via layers V1, V2, and the like are used to couple upper conductive layers.

Additional structures and operations for forming the CFET 200 are described in U.S. Pat. No. 10,977,417, U.S. Patent Application Publication No. 2024/0222429 A1, and U.S. Patent Application Publication No. 2024/0341092 A1, which are incorporated herein by reference in their entireties.

In FIGS. 2A-2C, the pair of first source/drain structures 218 and the pair of second source/drain structures 226 are all supplied with a same first reference or constant voltage by the corresponding first and second conductive structures 214, 230. In some embodiments, the first reference voltage applied to the first source/drain structures 218 and the second source/drain structures 226 is a first power source voltage, e.g., VDD. The gate structure 246 is supplied with a second reference or constant voltage, which is different from the first reference voltage. In some embodiments, the second reference voltage applied to the gate structure 246 is a second power source voltage, e.g., VSS. In some embodiments, the CFET 200 is configured so as to have all four of the sources and drains of the first transistor 200a and the second transistor 200b coupled to VDD and both of the gates of the first transistor 200a and the second transistor 200b coupled to VSS. In some embodiments, the CFET 200 so configured improves dynamic IR drop in a circuit by providing a capacitor between VDD and VSS. Further, the CFET 200 provides for internal electrical connections using the vertical electrical connection 234 and thus simplifies in-cell routing as compared to a device using a corresponding connection made outside the CFET.

FIG. 2D is a schematic diagram of the CFET 200 showing capacitive features according to some embodiments.

Referring to FIG. 2D, the CFET 200 supplied with the first and second reference voltages provides capacitive features in multiple regions. In the example in FIG. 2D, the CFET 200 is configured so as to have all of the source/drain regions coupled to VDD and the common gate coupled to VSS. The CFET 200 is thus configured to reverse-bias the NMOS transistor, which helps to provide additional capacitance and helps to keep gate leakage across a gate oxide layer low in the NMOS transistor. In some embodiments, the absence of a well for the NMOS transistor of the CFET 200 helps to avoid leakage that would otherwise occur when using a well for an NMOS transistor and coupling the NMOS transistor source and drain to VDD while coupling the gate to VSS.

In further detail, in FIG. 2D the CFET 200 includes a number of capacitive features C01 through C12. The capacitive features C01-C05 may be considered to be primarily associated with the first transistor 200a. The capacitive features C06-C12 may be considered to be primarily associated with the reverse-biased second transistor 200b.

Referring to FIG. 2D, capacitive feature C01 provides capacitance between the first side of the gate structure 246 and first conductive structure 214a, and capacitive feature C02 provides capacitance between the second side of the gate structure 246 and first conductive structure 214b. Capacitive feature C03 represents the oxide capacitance, which is the capacitance between a first channel region 238a and the gate structure 246. Capacitive feature C04 provides capacitance between the first side of the gate structure 246 and first first source/drain structure 218a, and capacitive feature C05 provides capacitance between the second side of the gate structure 246 and second first source/drain structure 218b. Capacitive feature C06 provides capacitance between the first side of the gate structure 246 and insulating structure 222a, and capacitive feature C07 provides capacitance between the second side of the gate structure 246 and insulating structure 222b. Capacitive feature C08 provides capacitance between the first side of the gate structure 246 and first second source/drain structure 226a, and capacitive feature C09 provides capacitance between the second side of the gate structure 246 and second second source/drain structure 226b. Capacitive feature C10 represents the oxide capacitance, which is the capacitance between a second channel region 242a and the gate structure 246. Capacitive feature C11 provides capacitance between the first side of the gate structure 246 and second conductive structure 230a, and capacitive feature C12 provides capacitance between the second side of the gate structure 246 and second conductive structure 230b.

The presence of the capacitive features C06-C12 significantly increases the overall capacitance of the capacitor-configured CFET 200 relative to a CFET that uses only one transistor, e.g., the first transistor 200a, to provide capacitance. A CFET that uses only one transistor to provide capacitance is not fully exploited for decoupling purposes. In contrast, according to some embodiments, the CFET 200 configured as a capacitor can significantly increase capacitance for decoupling, while occupying a same layout area as a CFET that uses only one transistor to provide capacitance. The CFET 200 configured as a capacitor can thus help minimize layout cell area devoted to decoupling capacitors.

FIG. 2E is a cross-sectional diagram of a structure of a CFET 200′ according to some embodiments. FIG. 2F is a cross-section along a line III-III′ in FIG. 2E.

Features discussed below in connection with FIGS. 2E-2F generally correspond to features discussed above in connection with FIGS. 2A-2C having corresponding numbers or labels. Features of FIGS. 2E-2F that are not specifically described below are the same as corresponding features of FIGS. 2A-2C having corresponding numbers or labels unless otherwise stated or otherwise apparent.

In some embodiments, the CFET 200′is used to implement the DCAP cell 100 using a split-gate configuration that employs an inversion charge on a channel to increase capacitance. In FIGS. 2E-2F, the common gate of the CFET 200 of FIGS. 2A-2C is substituted with a split-gate configuration in which the first transistor 200a has a gate structure 246a and the second transistor 200b has a separate gate structure 246b. An insulating structure 258 is between the gate structure 246a and the gate structure 246b, and isolates the gate structure 246a from the gate structure 246b.

In some embodiments, the vertical electrical connections 234 electrically connect the second conductive structures 230 to the first source/drain structures 218, and the second source/drain structures 226 and the first source/drain structures 218 are supplied with VDD while the gate structure 246a of the first transistor 200a and the gate structure 246b of the second transistor 200b are supplied with VSS.

In FIG. 2E, the insulating structure 258 has a height (in the Z-axis direction) that is less than the height of the insulating structure 222. In other embodiments, the insulating structure 258 and the insulating structure 222 have a same height. In some embodiments, the insulating structure 258 and the insulating structure 222 are formed using separate processes and/or different materials, while in other embodiments the insulating structure 258 and the insulating structure 222 are formed using a same process and/or same materials. In some embodiments, the insulating structure 258 is included in an MDI layer.

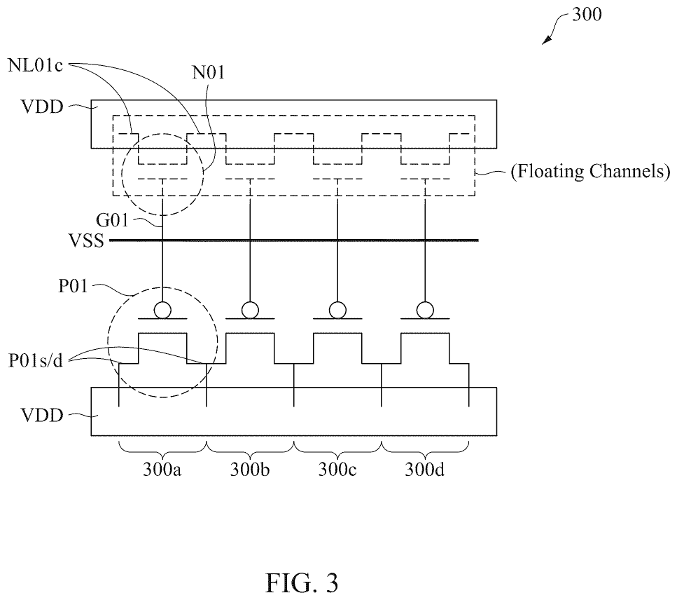

FIG. 3 is a schematic diagram of a DCAP cell 300 according to some embodiments.

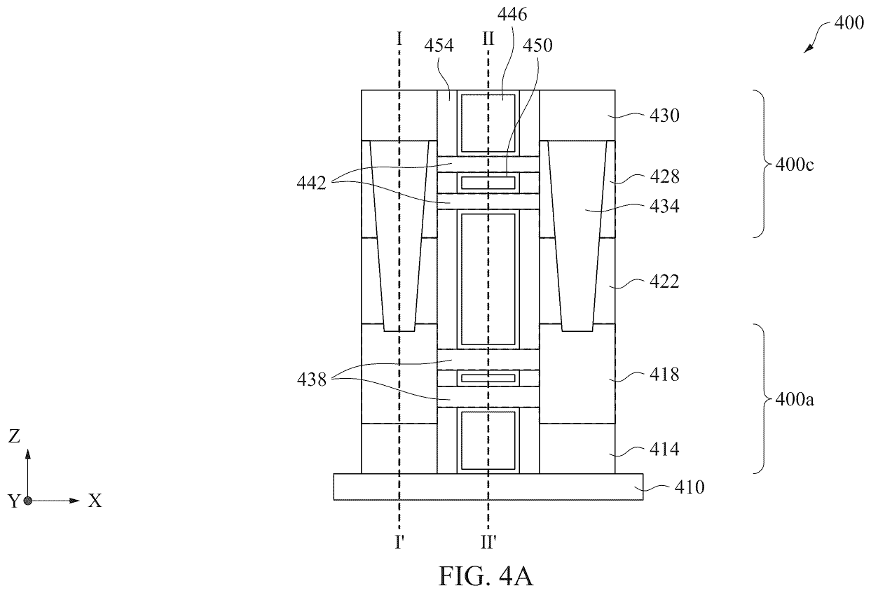

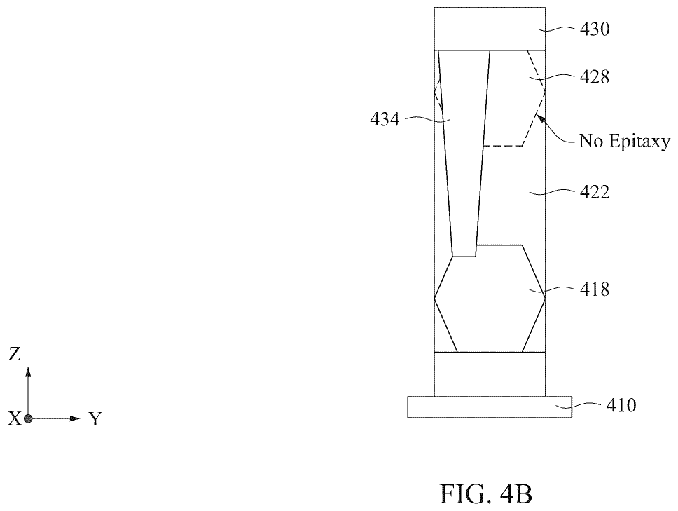

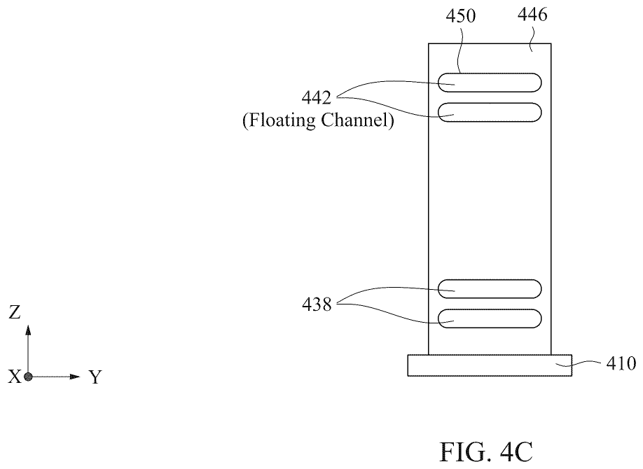

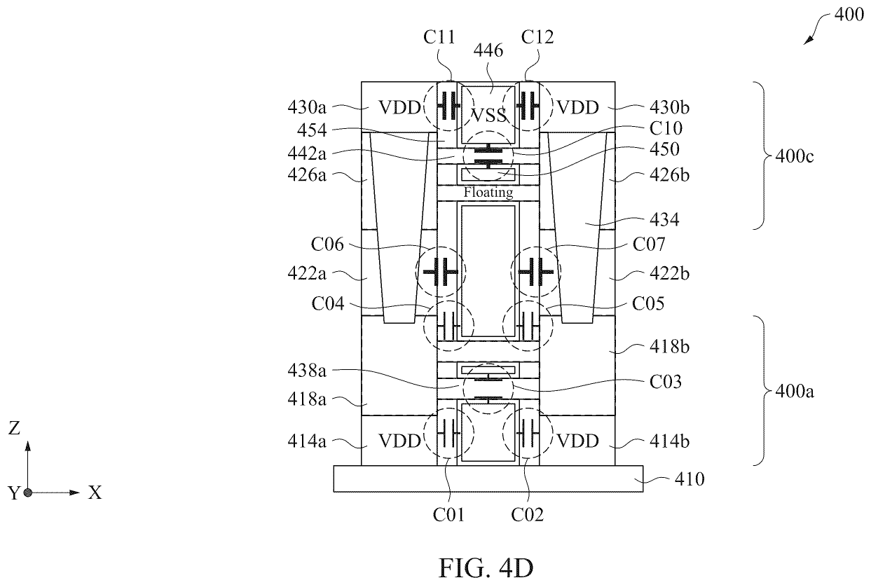

In FIG. 3, the DCAP cell 300 according to some embodiments includes four CFET-like devices 300a-300d by way of example. In other embodiments, the number of CFET-like devices is one, two, three, or more than four. First CFET device 300a includes a first PMOS transistor P01 and a first NMOS transistor-like device NL01, which have a common gate G01. The second through fourth CFET-like devices 300b-300d also each include a PMOS transistor and an NMOS transistor-like device with common gates. Source/drain (s/d) regions P01s/d of the first PMOS transistor P01 and contacts NL01c of the first NMOS transistor-like device NL01 are all supplied with a first reference voltage, e.g., a constant voltage, e.g., VDD, while the common gate G01 is supplied with a second reference voltage different from the first reference voltage, e.g., VSS. Channels of the first through fourth CFET-like devices 300a-300d are floated. As described in detail below in connection with FIGS. 4A-4D, the DCAP cell 300 thus configured provides additional capacitance relative to a DCAP cell using CFETs that employ only one transistor of each CFET, e.g., the PMOS transistor, to provide capacitance. Further, the advantage of increased capacitance provided by the DCAP cell 300 is achieved without an increase in cell size relative to a DCAP cell using CFETs that employ only one transistor of each CFET, e.g., the PMOS transistor, to provide capacitance.

FIG. 4A is a cross-sectional diagram of a structure of a CFET-like structure 400 according to some embodiments. FIG. 4B is a cross-section along a line I-I′ in FIG. 4A. FIG. 4C is a cross-section along a line II-II′ in FIG. 4A.

Features discussed below in connection with FIGS. 4A-4C generally correspond to features discussed above in connection with FIGS. 2A-2C, with numbering increased by 200. In some embodiments, features of FIGS. 4A-4C that are not specifically described below are the same as corresponding features of FIGS. 2A-2C unless otherwise stated or otherwise apparent.

In FIG. 4A, an NMOS transistor-like structure 400c according to some embodiments does not include second source/drain structures 226 of FIG. 2A. In some embodiments, the CFET-like structure 400 corresponds to any of CFET-like devices 300a-300d of FIG. 3.

In FIG. 4A, the CFET-like structure 400 according to some embodiments includes a PMOS transistor 400a on a substrate 410 and the NMOS transistor-like structure 400c on the PMOS transistor 400a, in a vertical arrangement such that, relative to a Z-axis direction, the PMOS transistor 400a is between the substrate 410 and the NMOS transistor-like structure 400c.

In FIG. 4A, the CFET-like structure 400 includes a pair of first conductive structures 414 spaced apart laterally in an X-axis direction on the substrate 410, a pair of first source/drain structures 418 on corresponding ones of the first conductive structures 414, a pair of insulating structures 422 on corresponding ones of the first source/drain structures 418, a pair of insulating structures 428 on corresponding ones of the insulating structures 222, and a pair of second conductive structures 230 on corresponding ones of the insulating structures 428. The CFET-like structure 400 also includes a pair of vertical electrical connections 434 extending in the Z-axis direction between and connecting corresponding ones of the first source/drain structures 418 and the second conductive structures 430. The CFET-like structure 400 also includes first channel regions 438 extending in the X-axis direction between the first source/drain structures 418, and second channel regions 442 extending in the X-axis direction between the insulating structures 428. In some embodiments, the second channel regions 442 are floated by the omission of NEPI (or PEPI) structures. A gate structure 446 extends in the Z-axis direction and at least partially surrounds the first and second channel regions 438, 442. In some embodiments, the gate structure 446 entirely surrounds the first and second channel regions 438, 442. The gate structure 446 is between ones of the pair of first conductive structures 414 and between ones of the pair of second conductive structures 430 relative to the X-axis direction. The gate structure 446 is at least partially covered by a gate isolation layer 450, e.g., a gate oxide. The gate isolation layer 450 is between the gate structure 446 and the first and second channel regions 438, 442. FIG. 4C shows the gate isolation layer 450 extending along surfaces of the gate structure 446 at regions apart from the first and second channel regions 438, 442, but it will be understood that other insulating structures can be used instead of the gate isolation layer 450 at the regions apart from the first and second channel regions 438, 442. An insulating structure 454 surrounds the gate structure 446. In some embodiments, the insulating structure 454 is integral with the insulating structures 422 and the insulating structures 428. In other embodiments, the insulating structure 454, the insulating structures 422, and/or the insulating structures 428 are formed separately and/or formed of different insulating materials. In some embodiments, the gate structure 446 is substituted with a split-gate structure such as that described above in connection with gate structures 246a, 246b of FIGS. 2E-F.

The second channel regions 442 extend between ones of the insulating structures 428. In some embodiments, the second channel regions 442 are active regions that include nanostructures such as nanosheets or nanowires. In FIG. 4A, the NMOS transistor-like structure 400c includes two second channel regions 442. In other embodiments, only one second channel region 442 is provided, and in still other embodiments, more than two second channel regions 442 are provided. In FIG. 4A, the number of first channel regions 438 is equal to the number of second channel regions 442. In other embodiments, the number of first channel regions 438 is different from the number of second channel regions 442, or the first channel regions 438 have different dimensions relative to the second channel regions 442. In some embodiments, each second channel region 442 includes a plurality of nanostructures. In some embodiments, the nanostructures are silicon nanostructures, e.g., silicon nanosheets or the like. In some embodiments, forming the silicon nanostructures includes forming alternating layers of SiGe and Si in a vertical stack, e.g., by sequentially forming SiGe and Si layers using an epitaxial process such one of the epitaxial processes described above, and then selectively removing the SiGe layers, e.g., using a selective etch, such that the Si layers remain as the second channel regions 442.

In some embodiments, the insulating structures 428 include an oxide of silicon, silicon nitride, SiOCN, or the like. In some embodiments, the insulating structures 428 are formed by, e.g., a deposition process or an oxidation process.

The vertical electrical connections 434 are formed of a conductive material that extends through the insulating structures 428 to connect corresponding ones of the first source/drain structures 418 and the second conductive structures 430. A first vertical electrical connection 434 is on a first side of the gate structure 446 and a second vertical electrical connection 434 is on a second side of the gate structure 446. In some embodiments, the vertical electrical connections 434 are formed before the second conductive structures 430. In other embodiments, the vertical electrical connections 434 are formed to penetrate the second conductive structures 430. In FIG. 4A, the vertical electrical connections 434 extend partially into the first source/drain structures 418. In other embodiments, the vertical electrical connections 434 extend through the first source/drain structures 418 to connect to the first conductive structures 414. In FIG. 4B, the vertical electrical connection 434 penetrates the insulating structure 428 and extends partially into the first source/drain structure 418. The vertical electrical connection 434 electrically connects the second conductive structure 430 to the first source/drain structure 418 such that the second conductive structure 430 and the first source/drain structure 418 are configured to be at a same voltage potential, e.g., VDD.

In FIG. 4A, the CFET-like structure 400 is configured as a capacitor, and the first source/drain structures 418 and the second conductive structures 430 are all supplied with a same first reference voltage. Other CFETs (e.g., in logic gates adjacent to the CFET-like structure 400) that are not configured as capacitors do not include the vertical electrical connections 434 connecting to the first source/drain structures 418.

FIG. 4D is a schematic diagram of the CFET-like structure 400 showing capacitive features according to some embodiments.

Referring to FIG. 4D, the CFET-like structure 400 supplied with the first and second reference voltages provides capacitive features in multiple regions. As described above, in some embodiments, the CFET-like structure 400 is configured so as to have the sources and drains of the PMOS transistor 400a coupled to VDD, the second conductive structures 430 coupled to VDD, and the common gate coupled to VSS. The CFET-like structure 400 is thus configured to provide additional capacitance relative to CFET that uses only a single transistor to provide capacitance, and helps to keep gate leakage across a gate oxide layer low at the second channel regions 442.

In further detail, in FIG. 4D the CFET-like structure 400 includes a number of capacitive features C01-C07, C11, and C12. The capacitive features C01-C05 may be considered to be primarily associated with the PMOS transistor 400a. The capacitive features C06, C07, C11, and C12 may be considered to be primarily associated with the NMOS transistor-like structure 400c.

Referring to FIG. 4D, capacitive feature C01 provides capacitance between the first side of the gate structure 446 and first conductive structure 414a, and capacitive feature C02 provides capacitance between the second side of the gate structure 446 and first conductive structure 414b. Capacitive feature C03 represents the oxide capacitance, which is the capacitance between a first channel region 438a and the gate structure 446. Capacitive feature C04 provides capacitance between the first side of the gate structure 446 and first first source/drain structure 418a, and capacitive feature C05 provides capacitance between the second side of the gate structure 446 and second first source/drain structure 418b. Capacitive feature C06 provides capacitance between the first side of the gate structure 446 and insulating structure 422a, and capacitive feature C07 provides capacitance between the second side of the gate structure 446 and insulating structure 422b. Capacitive feature C10 represents the oxide capacitance, which is the capacitance between a second channel region 442a and the gate structure 446. Capacitive feature C11 provides capacitance between the first side of the gate structure 446 and second conductive structure 430a, and capacitive feature C12 provides capacitance between the second side of the gate structure 446 and second conductive structure 430b.

The presence of the capacitive features C06, C07, C11, and C12 significantly increases the overall capacitance of the capacitor-configured CFET-like structure 400 relative to a CFET that uses only one transistor, e.g., the first transistor 200a, to provide capacitance. A CFET that uses only one transistor to provide capacitance is not fully exploited for decoupling purposes. In contrast, according to some embodiments, the CFET-like structure 400 configured as a capacitor can significantly increase capacitance for decoupling, while occupying a same layout area as a CFET that uses only one transistor to provide capacitance. The CFET-like structure 400 configured as a capacitor can thus help minimize layout cell area devoted to decoupling capacitors. Further, CFET-like structure 400 can provide more capacitance than a CFET that uses only one transistor to provide capacitance, while being amenable to a less complex manufacturing process than the CFET 200 due to omission of the NEPI (or PEPI) structures.

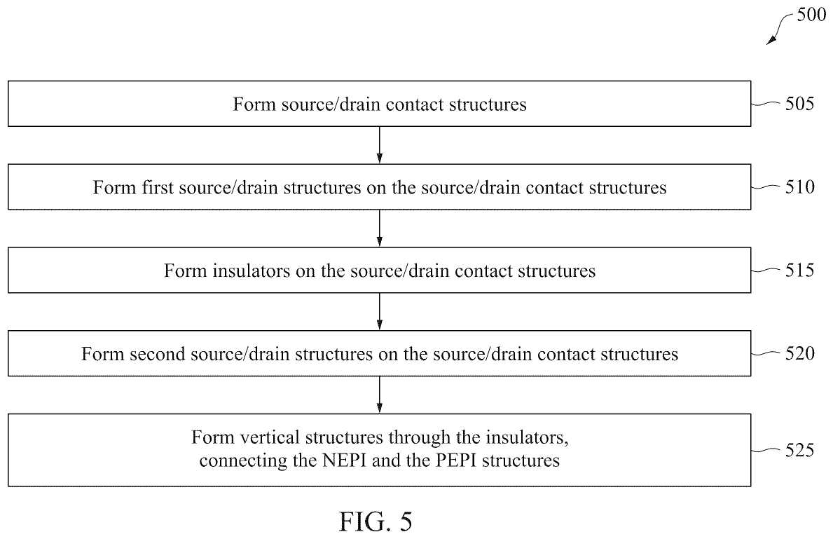

FIG. 5 is a flowchart of a method 500 of manufacturing a semiconductor device according to some embodiments.

The method 500 according to some embodiments includes an operation 505 of forming source/drain contact structures. In some embodiments, the source/drain contact structures formed in operation 505 are BMD structures that correspond to the pair of first conductive structures 214 of FIGS. 2A-2D and/or the pair of first conductive structures 414 of FIGS. 4A-4D.

The method 500 includes an operation 510 of forming first source/drain structures, e.g., PEPI (or NEPI) structures, on the source/drain contact structures. In some embodiments, the PEPI (or NEPI) structures formed in operation 510 correspond to the first source/drain structures 218 of FIGS. 2A-2D and/or the first source/drain structures 418 of FIGS. 4A-4D.

The method 500 includes an operation 515 of forming insulators on the source/drain contact structures. In some embodiments, the insulators formed in operation 515 correspond to the insulating structures 222 of FIGS. 2A-2D and/or the insulating structures 422 of FIGS. 4A-4D.

The method 500 includes an operation 520 of forming second source/drain structures, e.g., NEPI (or PEPI) structures, on the source/drain contact structures. In some embodiments, the NEPI (or PEPI) structures formed in operation 520 correspond to the second source/drain structures 226 of FIGS. 2A-2D. In modified embodiments, operation 520 is omitted and NEPI (or PEPI) structures are not formed, e.g., as in the CFET-like structure 400 of FIGS. 4A-4D.

The method 500 includes an operation 525 of forming vertical structures through the insulators, connecting the first and the second source/drain structures. In some embodiments, the vertical structures formed in operation 525 correspond to the vertical electrical connections 234 of FIGS. 2A-2D. In modified embodiments, operation 525 forms the vertical structure through the insulators, connecting the second conductive structures 430 and the first source/drain structures, and the vertical structures formed thereby correspond to the vertical electrical connections 434 of FIGS. 4A-4D.

The embodiments and modified embodiments described above in connection with FIG. 5 are usable to form the CFET devices and CFET-like devices of the DCAP cells 100 and 300 described above in connection with FIGS. 1 and 3.

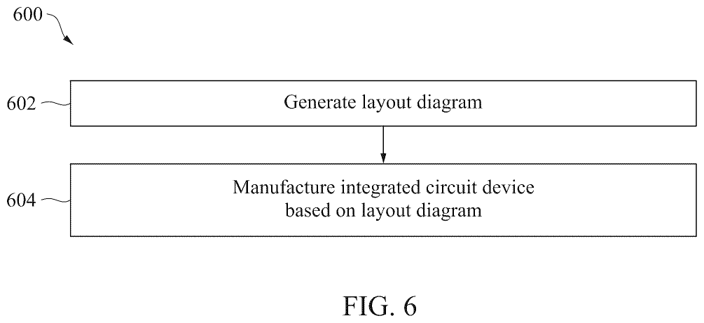

FIG. 6 is a flowchart of a method 600 of manufacturing a semiconductor device according to some embodiments.

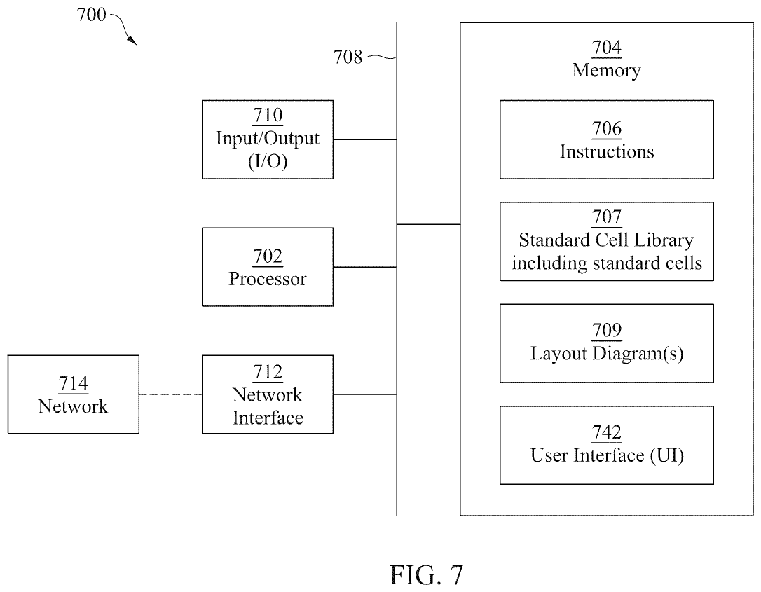

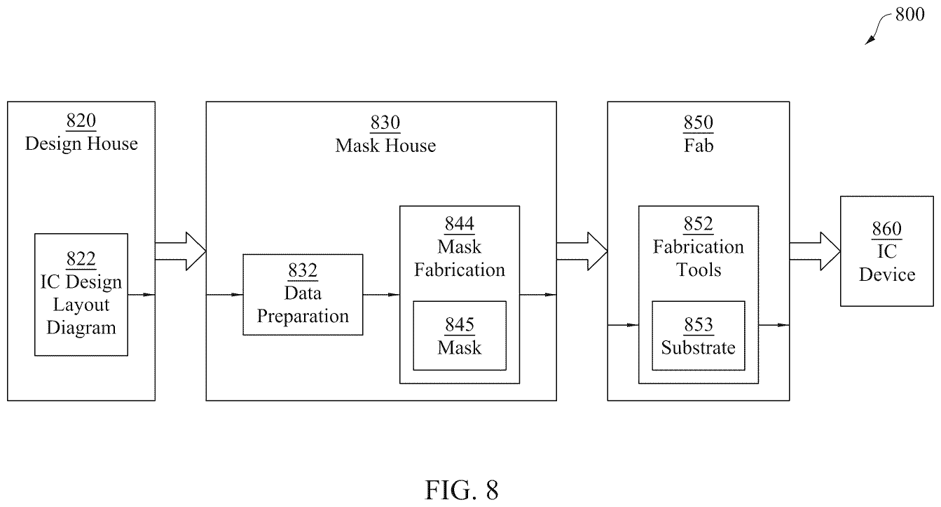

Method 600 is implementable, for example, using EDA system 700 (FIG. 7, discussed below) and an integrated circuit (IC), manufacturing system 800 (FIG. 8, discussed below), in accordance with some embodiments. Examples of a semiconductor device which can be manufactured according to method 600 include CFET 200 of FIG. 2 or the like.

In FIG. 6, method 600 includes blocks 602-604. At block 602, a layout diagram is generated which, among other things, includes one or more of layout diagrams disclosed herein, or the like. Block 602 is implementable, for example, using EDA system 700 (FIG. 7, discussed below), in accordance with some embodiments. In some embodiments, block 602 includes generating shapes corresponding to structures in a semiconductor diagram which are to be represented.

At block 604, based on the layout diagram, at least one of (A) one or more photolithographic exposures are made or (B) one or more semiconductor masks are fabricated or (C) one or more components in a layer of an integrated circuit (IC) device, e.g., a semiconductor device, are fabricated. See discussion below of FIG. 8.

FIG. 7 is a block diagram of an electronic design automation (EDA) system 700 according to some embodiments.

In some embodiments, EDA system 700 includes an automatic placement and routing (APR) system. Methods described herein of designing layout diagrams represent wire routing arrangements, in accordance with one or more embodiments, are implementable, for example, using EDA system 700, in accordance with some embodiments.

In some embodiments, EDA system 700 is a general purpose computing device including a hardware processor 702 and a non-transitory, computer-readable storage medium 704. Computer-readable storage medium 704, amongst other things, is encoded with, i.e., stores, computer program code 706, i.e., a set of executable instructions. Execution of instructions 706 by processor 702 represents (at least in part) an EDA tool which implements a portion or all of the methods described herein in accordance with one or more embodiments (hereinafter, the noted processes and/or methods).

Processor 702 is electrically coupled to computer-readable storage medium 704 via a bus 708. Processor 702 is also electrically coupled to an I/O interface 710 by bus 708. A network interface 712 is also electrically connected to processor 702 via bus 708. Network interface 712 is connected to a network 714, so that processor 702 and computer-readable storage medium 704 are capable of connecting to external elements via network 714. Processor 702 is configured to execute computer program code 706 encoded in computer-readable storage medium 704 in order to cause EDA system 700 to be usable for performing a portion or all of the noted processes and/or methods. In one or more embodiments, processor 702 is a central processing unit (CPU), a multi-processor, a distributed processing system, an application specific integrated circuit (ASIC), and/or a suitable processing unit.

In one or more embodiments, computer-readable storage medium 704 is an electronic, magnetic, optical, electromagnetic, infrared, and/or a semiconductor system (or apparatus or device). For example, computer-readable storage medium 704 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 704 includes a compact disk-read only memory (CD-ROM), a compact disk-read/write (CD-R/W), and/or a digital video disc (DVD).

In one or more embodiments, computer-readable storage medium 704 stores computer program code 706 configured to cause EDA system 700 (where such execution represents (at least in part) the EDA tool) to be usable for performing a portion or all of the noted processes and/or methods. In one or more embodiments, computer-readable storage medium 704 also stores information which facilitates performing a portion or all of the noted processes and/or methods. In one or more embodiments, computer-readable storage medium 704 stores library 707 of standard cells including such standard cells as disclosed herein. In one or more embodiments, computer-readable storage medium 704 stores one or more layout diagrams 709 corresponding to one or more layouts disclosed herein.

EDA system 700 includes I/O interface 710. I/O interface 710 is coupled to external circuitry. In one or more embodiments, I/O interface 710 includes a keyboard, keypad, mouse, trackball, trackpad, touchscreen, and/or cursor direction keys for communicating information and commands to processor 702.

EDA system 700 also includes network interface 712 coupled to processor 702. Network interface 712 allows EDA system 700 to communicate with network 714, to which one or more other computer systems are connected. Network interface 712 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 700.

EDA system 700 is configured to receive information through I/O interface 710. The information received through I/O interface 710 includes one or more of instructions, data, design rules, libraries of standard cells, and/or other parameters for processing by processor 702. The information is transferred to processor 702 via bus 708. EDA system 700 is configured to receive information related to a user interface (UI) through I/O interface 710. The information is stored in computer-readable storage medium 704 as UI 742.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 700. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 8 is a block diagram of an integrated circuit (IC) manufacturing system 800, and an IC manufacturing flow associated therewith, according to some embodiments. In some embodiments, based on a layout diagram, at least one of (A) one or more semiconductor masks or (B) at least one component in a layer of a semiconductor integrated circuit is fabricated using IC manufacturing system 800.

In FIG. 8, IC manufacturing system 800 includes entities, such as a design house 820, a mask house 830, and an IC manufacturer/fabricator (fab) 850, that interact with one another in the design, development, and manufacturing cycles and/or services related to manufacturing an IC device 860. The entities in IC manufacturing system 800 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 820, mask house 830, and IC fab 850 is owned by a single larger company. In some embodiments, two or more of design house 820, mask house 830, and IC fab 850 coexist in a common facility and use common resources.

Design house (or design team) 820 generates an IC design layout diagram 822. IC design layout diagram 822 includes various geometrical patterns designed for an IC device 860. The geometrical patterns correspond to patterns of metal, oxide, or semiconductor layers that make up the various components of IC device 860 to be fabricated. The various layers combine to form various IC features. For example, a portion of IC design layout diagram 822 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 820 implements a proper design procedure to form IC design layout diagram 822. The design procedure includes one or more of logic design, physical design or place and route. IC design layout diagram 822 is presented in one or more data files having information of the geometrical patterns. For example, IC design layout diagram 822 can be expressed in a GDSII file format or DFII file format.

Mask house 830 includes mask data preparation 832 and mask fabrication 844. Mask house 830 uses IC design layout diagram 822 to manufacture one or more masks 845 to be used for fabricating the various layers of IC device 860 according to IC design layout diagram 822. Mask house 830 performs mask data preparation 832, where IC design layout diagram 822 is translated into a representative data file (RDF). Mask data preparation 832 provides the RDF to mask fabrication 844. Mask fabrication 844 includes a mask writer. A mask writer converts the RDF to an image on a substrate, such as a mask (reticle) 845 or a substrate 853, e.g., a semiconductor wafer 853. The IC design layout diagram 822 is manipulated by mask data preparation 832 to comply with particular characteristics of the mask writer and/or requirements of IC fab 850. In FIG. 8, mask data preparation 832 and mask fabrication 844 are illustrated as separate elements. In some embodiments, mask data preparation 832 and mask fabrication 844 can be collectively referred to as mask data preparation.

In some embodiments, mask data preparation 832 includes optical proximity correction (OPC) which uses lithography enhancement techniques to compensate for image errors, such as those that can arise from diffraction, interference, other process effects and the like. OPC adjusts IC design layout diagram 822. In some embodiments, mask data preparation 832 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 832 includes a mask rule checker (MRC) that checks the IC design layout diagram 822 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 822 to compensate for photolithographic implementation effects during mask fabrication 844, which may undo part of the modifications performed by OPC in order to meet mask creation rules.

In some embodiments, mask data preparation 832 includes lithography process checking (LPC) that simulates processing that will be implemented by IC fab 850 to fabricate IC device 860. LPC simulates this processing based on IC design layout diagram 822 to create a simulated manufactured device, such as IC device 860. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 822.

It should be understood that the above description of mask data preparation 832 has been simplified for the purpose of clarity. In some embodiments, mask data preparation 832 includes additional features such as a logic operation (LOP) to modify the IC design layout diagram 822 according to manufacturing rules. Additionally, the processes applied to IC design layout diagram 822 during mask data preparation 832 may be executed in a variety of different orders.

After mask data preparation 832 and during mask fabrication 844, a mask 845 or a group of masks 845 are fabricated based on the modified IC design layout diagram 822. In some embodiments, mask fabrication 844 includes performing one or more lithographic exposures based on IC design layout diagram 822. In some embodiments, an electron-beam (e-beam) or a mechanism of multiple e-beams is used to form a pattern on a mask (photomask or reticle) 845 based on the modified IC design layout diagram 822. Mask 845 can be formed in various technologies. In some embodiments, mask 845 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 845 includes a transparent substrate (e.g., fused quartz) and an opaque material (e.g., chromium) coated in the opaque regions of the binary mask. In another example, mask 845 is formed using a phase shift technology. In a phase shift mask (PSM) version of mask 845, various features in the pattern formed on the phase shift mask are configured to have proper phase difference to enhance the resolution and imaging quality. In various examples, the phase shift mask can be attenuated PSM or alternating PSM. The mask(s) generated by mask fabrication 844 is used in a variety of processes. For example, such a mask(s) is used in an ion implantation process to form various doped regions in semiconductor wafer 853, in an etching process to form various etching regions in semiconductor wafer 853, and/or in other suitable processes.

IC fab 850 is an IC fabrication business that includes one or more manufacturing facilities for the fabrication of a variety of different IC products. In some embodiments, IC fab 850 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 850 includes fabrication tools 852 configured to execute various manufacturing operations on semiconductor wafer 853 such that IC device 860 is fabricated in accordance with the mask(s), e.g., mask 845. In various embodiments, fabrication tools 852 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 850 uses mask(s) 845 fabricated by mask house 830 to fabricate IC device 860. Thus, IC fab 850 at least indirectly uses IC design layout diagram 822 to fabricate IC device 860. In some embodiments, semiconductor wafer 853 is fabricated by IC fab 850 using mask(s) 845 to form IC device 860. In some embodiments, the IC fabrication includes performing one or more lithographic exposures based at least indirectly on IC design layout diagram 822. Semiconductor wafer 853 includes a silicon substrate or other proper substrate having material layers formed thereon. Semiconductor wafer 853 further includes one or more of various doped regions, dielectric features, multilevel interconnects, and the like (formed at subsequent manufacturing steps).

Details regarding an integrated circuit (IC) manufacturing system (e.g., the IC manufacturing system 800 of FIG. 9), and an IC manufacturing flow associated therewith are found, e.g., in U.S. Pat. No. 9,256,709, granted Feb. 9, 2016, U.S. Pre-Grant Publication No. 2015/0278429, published Oct. 1, 2015, U.S. Pre-Grant Publication No. 2014/0040838, published Feb. 6, 2014, and U.S. Pat. No. 7,260,442, granted Aug. 21, 2007, the entireties of each of which are hereby incorporated by reference.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless otherwise specified.

In some embodiments, a complementary field effect transistor (CFET) includes first source/drain regions of a first conductivity type; an insulating layer on the first source/drain regions; second source/drain regions of a second conductivity type on the insulating layer, the second conductivity type being different from the first conductivity type; vertical connecting structures extending through the insulating layer and electrically connecting the first source/drain regions with the second source/drain regions, the first and second source/drain regions being configured to receive a same first reference voltage; a first channel region corresponding to the first source/drain regions; a second channel region corresponding to the second source/drain regions; and a gate structure that is common to and at least partially surrounds the first channel region and the second channel region, the gate structure being configured to receive a second reference voltage different from the first reference voltage.

In some embodiments, the CFET further includes first conductive structures, the first source/drain regions being on and electrically connected to the first conductive structures; and second conductive structures on the second source/drain regions, the second conductive structures being on and electrically connected to the vertical connecting structures. In some embodiments, the vertical connecting structures include a first vertical connecting structure that extends through a full height of a first one of the second source/drain regions, and the vertical connecting structures include a second vertical connecting structure that extends through a full height of a second one of second source/drain regions. In some embodiments, the first vertical connecting structure extends into a first one of the first source/drain regions, and the second vertical connecting structure extends into a second one of the first source/drain regions. In some embodiments, the first vertical connecting structure extends into a first one of the first source/drain regions by less than a half-height of the first one of the first source/drain regions, and the second vertical connecting structure extends into a second one of the first source/drain regions by less than a half-height of the second one of the first source/drain regions. In some embodiments, the first and second source/drain regions are epitaxial regions. In some embodiments, the vertical connecting structures are offset relative to a centerline of the epitaxial regions. In some embodiments, the first reference voltage is VDD, the second reference voltage is VSS, the first conductivity type is p-type, and the second conductivity type is n-type. In some embodiments, the first reference voltage is VSS, the second reference voltage is VDD, the first conductivity type is n-type, and the second conductivity type is p-type. In some embodiments, a plurality of the CFETs are coupled together in parallel in a decoupling capacitor (DCAP) circuit, all source/drain regions of the CFETs of the DCAP circuit being configured to receive VDD and all gate structures of the CFETs of the DCAP circuit being configured to receive VSS.

In some embodiments, a CFET includes first source/drain regions of a first conductivity type; an insulating layer on the first source/drain regions; second source/drain regions of a second conductivity type on the insulating layer, the second conductivity type being different from the first conductivity type; vertical connecting structures extending through the insulating layer and electrically connecting the first source/drain regions with the second source/drain regions, the first and second source/drain regions being configured to receive a same first reference voltage; a first channel region corresponding to the first source/drain regions; a second channel region corresponding to the second source/drain regions; a first gate structure that at least partially surrounds the first channel region; and a second gate structure that at least partially surrounds the second channel region, the first and second gate structures being configured to receive a second reference voltage different from the first reference voltage.

In some embodiments, the CFET further includes an insulating structure between the first channel region and the second channel region. In some embodiments, the first and second source/drain regions are epitaxial regions. In some embodiments, the first reference voltage is VDD and the second reference voltage is VSS, and the first conductivity type is p-type and the second conductivity type is n-type. In some embodiments, the first reference voltage is VSS and the second reference voltage is VDD, and the first conductivity type is n-type and the second conductivity type is p-type. In some embodiments, a plurality of the CFETs are coupled together in parallel in a decoupling capacitor (DCAP) circuit, all source/drain regions of the CFETs of the DCAP circuit being configured to receive VDD and all gate structures of the CFETs of the DCAP circuit being configured to receive VSS.

In some embodiments, a CFET includes first source/drain regions; an insulating layer on the first source/drain regions; conductive structures on the insulating layer; vertical connecting structures extending through the insulating layer and electrically connecting the first source/drain regions with the conductive structures, the first source/drain regions and conductive structures being configured to receive a same first reference voltage; a first channel region corresponding to the first source/drain regions; a second channel region at an upper portion of the insulating layer proximate to the conductive structures; and a gate structure that is common to and at least partially surrounds the first channel region and the second channel region, the gate structure being configured to receive a second reference voltage different from the first reference voltage.

In some embodiments, the second channel region is free of corresponding source/drain regions. In some embodiments, the second channel region is configured to float. In some embodiments, the first reference voltage is VDD and the second reference voltage is VSS, and the first source/drain regions are p-type. In some embodiments, the first reference voltage is VSS and the second reference voltage is VDD, and the first source/drain regions are n-type. In some embodiments, a plurality of the CFETs are coupled together in parallel in a decoupling capacitor (DCAP) circuit, all source/drain regions of the CFETs of the DCAP circuit being configured to receive VDD and all gate structures of the CFETs of the DCAP circuit being configured to receive VSS.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A complementary field effect transistor (CFET) comprising:
first source/drain regions of a first conductivity type;
an insulating layer on the first source/drain regions;
second source/drain regions of a second conductivity type on the insulating layer, the second conductivity type being different from the first conductivity type;
vertical connecting structures extending through the insulating layer and electrically connecting the first source/drain regions with the second source/drain regions, the first and second source/drain regions being configured to receive a same first reference voltage;
a first channel region corresponding to the first source/drain regions;
a second channel region corresponding to the second source/drain regions; and
a gate structure that is common to and at least partially surrounds the first channel region and the second channel region, the gate structure being configured to receive a second reference voltage different from the first reference voltage.

2. The CFET of claim 1, further comprising:
first conductive structures, the first source/drain regions being on and electrically connected to the first conductive structures; and
second conductive structures on the second source/drain regions, the second conductive structures being on and electrically connected to the vertical connecting structures.

3. The CFET of claim 1, wherein:
the vertical connecting structures include a first vertical connecting structure that extends through a full height of a first one of the second source/drain regions, and
the vertical connecting structures include a second vertical connecting structure that extends through a full height of a second one of second source/drain regions.

4. The CFET of claim 3, wherein:
the first vertical connecting structure extends into a first one of the first source/drain regions, and
the second vertical connecting structure extends into a second one of the first source/drain regions.

5. The CFET of claim 3, wherein:
the first vertical connecting structure extends into a first one of the first source/drain regions by less than a half-height of the first one of the first source/drain regions, and
the second vertical connecting structure extends into a second one of the first source/drain regions by less than a half-height of the second one of the first source/drain regions.

6. The CFET of claim 1, wherein:
the first and second source/drain regions are epitaxial regions.

7. The CFET of claim 6, wherein:
the vertical connecting structures are offset relative to a centerline of the epitaxial regions.

8. The CFET of claim 1, wherein:
the first reference voltage is VDD, and
the second reference voltage is VSS.

9. The CFET of claim 8, wherein:
the first conductivity type is p-type, and
the second conductivity type is n-type.

10. The CFET of claim 9, wherein:
a plurality of the CFETs are coupled together in parallel in a decoupling capacitor (DCAP) circuit, all source/drain regions of the CFETs of the DCAP circuit being configured to receive VDD and all gate structures of the CFETs of the DCAP circuit being configured to receive VSS.

11. A complementary field effect transistor (CFET) comprising:
first source/drain regions of a first conductivity type;
an insulating layer on the first source/drain regions;
second source/drain regions of a second conductivity type on the insulating layer, the second conductivity type being different from the first conductivity type;
vertical connecting structures extending through the insulating layer and electrically connecting the first source/drain regions with the second source/drain regions, the first and second source/drain regions being configured to receive a same first reference voltage;
a first channel region corresponding to the first source/drain regions;
a second channel region corresponding to the second source/drain regions;
a first gate structure that at least partially surrounds the first channel region; and
a second gate structure that at least partially surrounds the second channel region,
the first and second gate structures being configured to receive a second reference voltage different from the first reference voltage.

12. The CFET of claim 11, further comprising:
an insulating structure between the first channel region and the second channel region.

13. The CFET of claim 11, wherein:
the first and second source/drain regions are epitaxial regions.

14. The CFET of claim 11, wherein:
the first reference voltage is VDD and the second reference voltage is VSS, and
the first conductivity type is p-type, and the second conductivity type is n-type.

15. The CFET of claim 14, wherein:
a plurality of the CFETs are coupled together in parallel in a decoupling capacitor (DCAP) circuit, all source/drain regions of the CFETs of the DCAP circuit being configured to receive VDD and all gate structures of the CFETs of the DCAP circuit being configured to receive VSS.

16. A complementary field effect transistor (CFET) comprising:
first source/drain regions;
an insulating layer on the first source/drain regions;
conductive structures on the insulating layer;
vertical connecting structures extending through the insulating layer and electrically connecting the first source/drain regions with the conductive structures, the first source/drain regions and conductive structures being configured to receive a same first reference voltage;
a first channel region corresponding to the first source/drain regions;
a second channel region at an upper portion of the insulating layer proximate to the conductive structures; and
a gate structure that is common to and at least partially surrounds the first channel region and the second channel region, the gate structure being configured to receive a second reference voltage different from the first reference voltage.

17. The CFET of claim 16, wherein:
the second channel region is free of corresponding source/drain regions.

18. The CFET of claim 16, wherein:
the second channel region is configured to float.

19. The CFET of claim 16, wherein:
the first reference voltage is VDD and the second reference voltage is VSS, and
the first source/drain regions are p-type.

20. The CFET of claim 19, wherein:
a plurality of the CFETs are coupled together in parallel in a decoupling capacitor (DCAP) circuit, all source/drain regions of the CFETs of the DCAP circuit being configured to receive VDD and all gate structures of the CFETs of the DCAP circuit being configured to receive VSS.
